(19) United States
(12) Patent Application Publication
(10) Pub. No.: US 2003/0013327 A1
(43) Pub. Date: Jan. 16, 2003

(54) Connector

(76) Inventor: Yoon-Sik Choi, Kwangju (KR)

Correspondence Address: Norman P Soloway, Hayes Soloway, 130 W Cushing Street, Tucson, AZ, 85701, US

(21) Appl. No.: 10/204,013

(22) PCT Filed: Dec. 19, 2001
(86) PCT No.: PCT/KR01/02202

(30) Foreign Application Priority Data
Dec. 26, 2000 (KR) 2000/36367 U

(51) Int. Cl. H05K 1/00

(52) U.S. Cl. 439/74

(57) ABSTRACT

Disclosed is a connector for connecting boards that is provided with male and female terminals being coupled with each other, thereby preventing the separation of contact between the male and female terminals even upon application of impacts and avoiding the generation of bad contact caused due to heat or other factors.

### TECHNICAL FIELD

The present invention relates to a connector for connecting boards, and more particularly, to a connector that is provided with male and female terminals being coupled with each other, thereby preventing the separation of contact between the male and female terminals even upon application of impacts and avoiding the generation of bad contact caused due to heat or other factors.

### BACKGROUND ART

A connector, which is generally used in the field of electrical and electronic industries, is a means for connecting two or more electrical or electronic parts. With the development of the electrical and electronic industries, this is considered as a requisite. In other words, the connector is always needed in case where it is difficult to manufacture two or more products as a unitary body or in case where products have to be separately manufactured from the view point of effective production.

Therefore, the connector may take various shapes in accordance with the characteristics of the products used, and particularly, in the field of electrical and electronic industries it is desirable that it is capable of keeping most stable contact and making constant current flowing.

A conventionally developed connector for connecting boards is provided with a slot type of holder that covers terminals, for the purpose of exhibiting such the characteristics of the connector.

As shown in FIGS. 1A to 2B, the conventional connector is provided with a female connector unit 10 having a plurality of female terminals 12 that are arranged on the both sides of the interior of a single slot 11 formed thereon and a male connector unit 20 adapted to be inserted into the slot 11 and having a protrusion 21 that is disposed on the both sides thereof with a plurality of male terminals 22 arranged thereon.

In the conventional connector, however, the terminals (+, −) are arranged on the both sides of the single slot 11 and the plurality of male terminals 22 are bent with the protrusion 21 and then inserted into the slot 11, such that when the connector is used for a long period of time, it may lose its elasticity due to the heat by resistance or the impacts by external force, which makes contact between the male and female terminals substantially unstable. In other words, the problem in the contact of the connector causes the product with the corresponding connector to be out of order, with a result that the whole substrate on which the corresponding connector is mounted should be exchanged.

With the miniature of products, especially, the contact area of the connector becomes greatly reduced, and if slight separation of the contact is generated, the above-discussed problems become more obvious.

### DISCLOSURE OF INVENTION

It is an object of the present invention to provide a connector that is provided with male and female terminals being coupled with each other, thereby preventing the separation of contact between the male and female terminals even upon application of impacts and avoiding the generation of bad contact caused due to heat or other factors.

To accomplish this and other objects of the present invention, there is provided a connector for connecting boards that includes a female connector unit with a pair of substantially long slots on the one side thereof and a fixed protrusion for the one board on the side opposite to the one side on which the pair of slots are formed and a male connector unit with a pair of protrusions inserted correspondingly into the pair of slots and a fixed protrusion for the other board on the side opposite to the one side on which the pair of protrusions are formed, the connector being characterized in that the female connector unit has the pair of slots that are divided into electrodes ‘+’ and ‘−’ on the top portion of the one side thereof and a plurality of female terminals that are of a shape of “I” to be inserted into the slots in a symmetrically arranged manner, each of the plurality of female terminals, having a pair of legs of a shape of “U” into which each of a plurality of male terminals is connected and each of the legs provided with a first locking protrusion on the inner side of the end portion thereof, and the male connector unit has the pair of protrusions that are divided into the electrodes ‘+’ and ‘−’ on the top portion of the one side thereof and inserted into the slots and the plurality of male terminals that are of a shape of “L” to be inserted into the pair of protrusions in a symmetrically arranged manner, each of the plurality of male terminals having a leg as a portion connected to each of the plurality of female terminals that is inserted and fixed into each of the pair of protrusions and the leg provided with a second locking protrusion that is engaged with the first locking protrusion of each of the plurality of female terminals, on the outer side of the end portion thereof.

Preferably, the plurality of female terminals and the plurality of male terminals, which are inserted correspondingly into the female connector unit and the male connector unit, are formed by cutting working from sheet metal.

### BRIEF DESCRIPTION OF THE DRAWINGS

Further objects and advantages of the invention can be more fully understood from the following detailed description taken in conjunction with the accompanying drawings, in which:

FIG. 1A is a plan view of a conventional female connector unit;

FIG. 1B is a side sectional view of the female connector unit in FIG. 1A;

FIG. 2A is a plan view of a conventional male connector unit;

FIG. 2B is a side sectional view of the male connector unit in FIG. 2A;

FIG. 3A is a schematic perspective view of a female connector unit in the connector according to the present invention;

FIG. 3B is a perspective view of the internal structure of the female connector unit in FIG. 3A;

FIG. 4A is a schematic perspective view of a male connector unit in the connector according to the present invention;

FIG. 4B is a perspective view of the internal structure of the male connector unit in FIG. 4A;

FIG. 5 is a sectional view of the male and female connector units in the connector according to the present invention; and

FIG. 6 is a sectional view of the female and male terminals inserted into the connector according to the present invention.

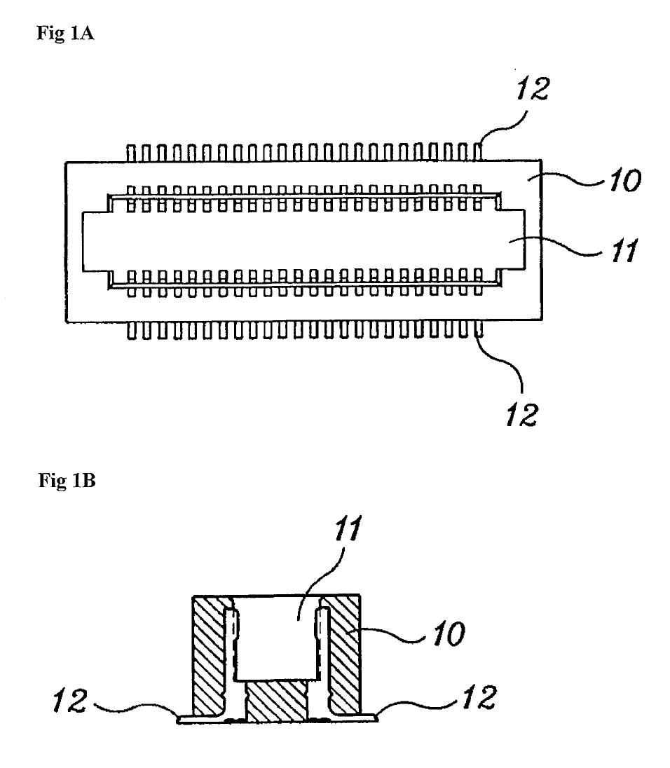

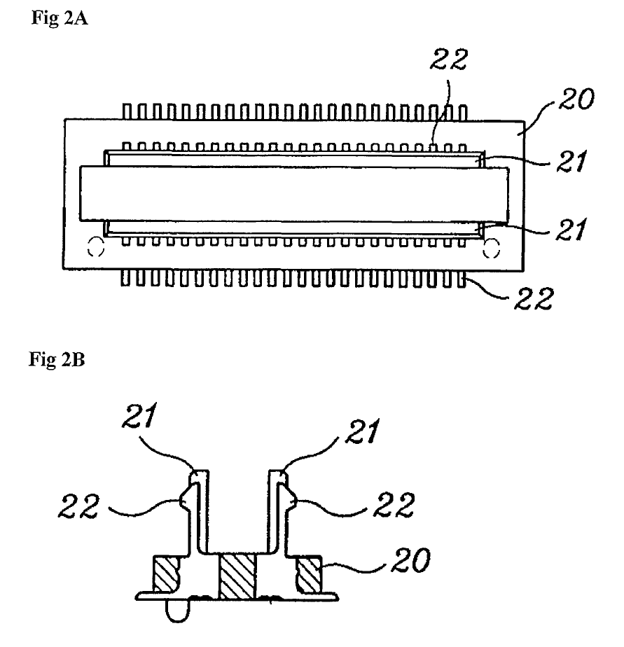

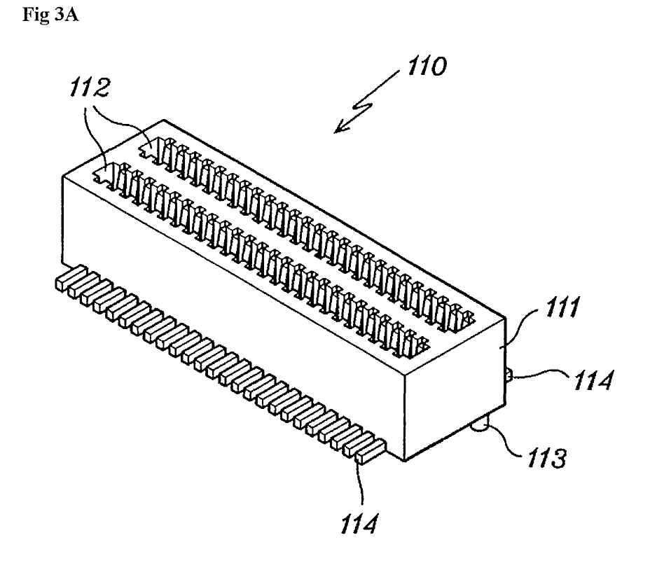

### BEST MODE FOR CARRYING OUT THE INVENTION

Hereinafter, an explanation of the configuration of a connector according to the present invention will be described with reference to the accompanying drawings.

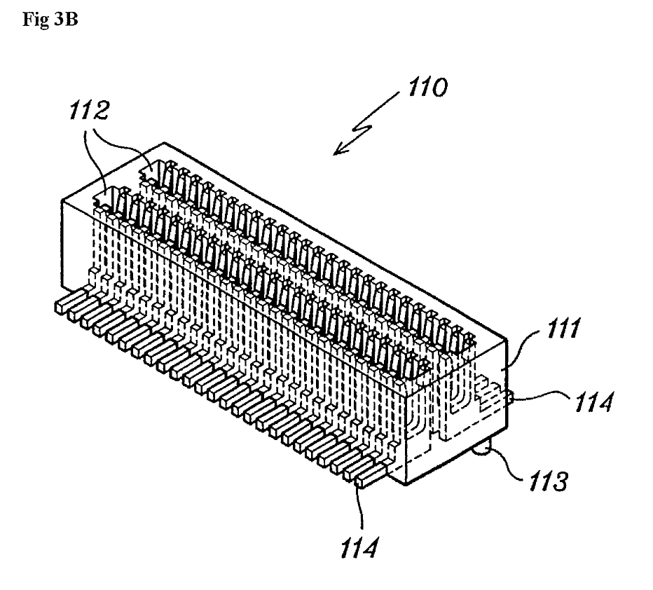

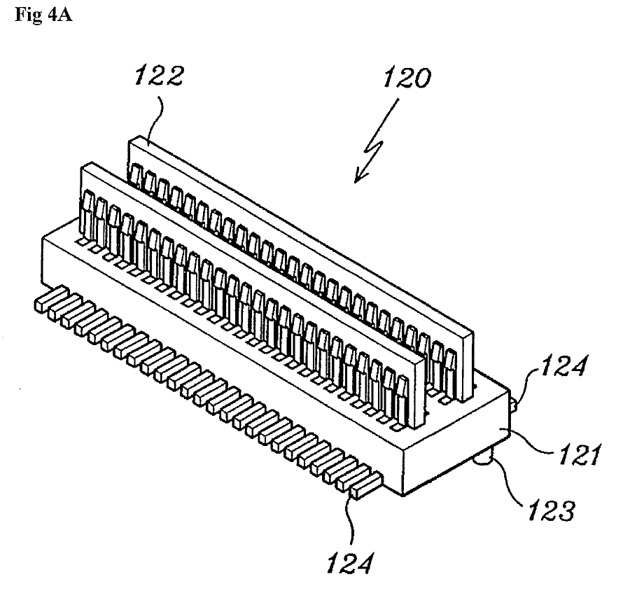

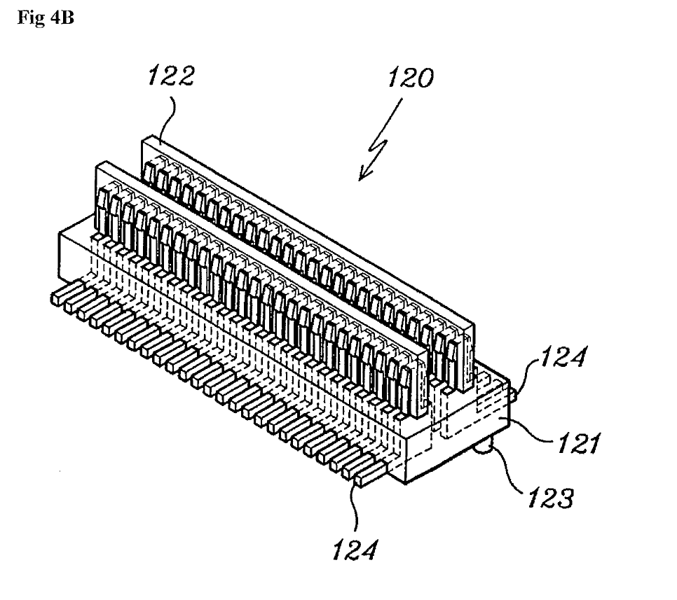

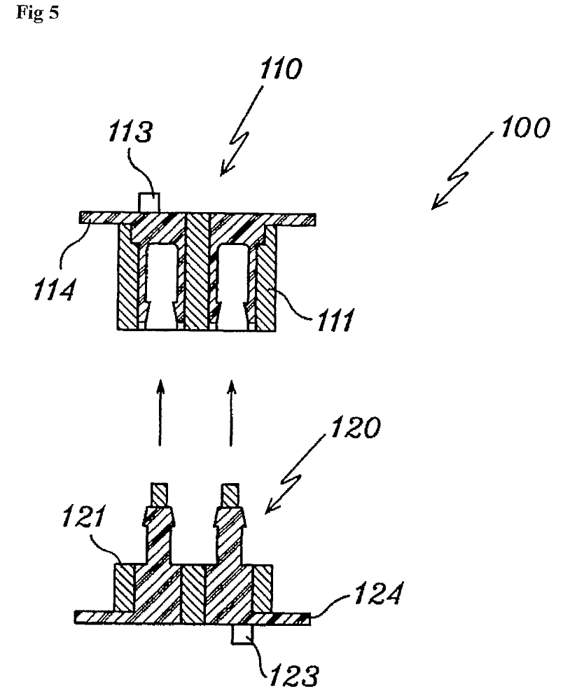

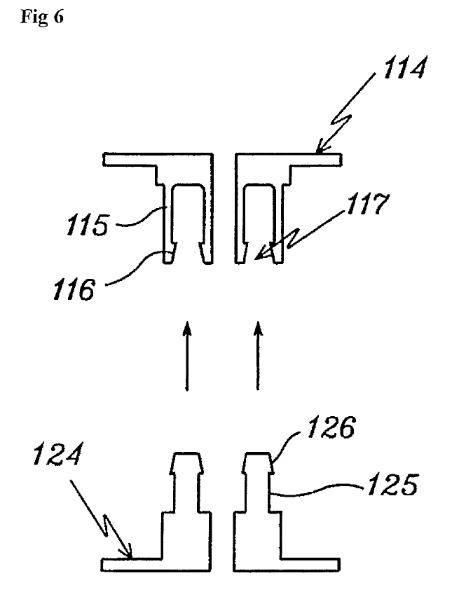

FIGS. 3A to 4B show the schematic perspective views for a connector 100 constructed according to the present invention.

The connector 100 according to the present invention includes a female connector unit 110 that is provided with a pair of substantially long slots 112 on the top portion of the one side of a holder 111 and a fixed protrusion 113 adapted to be fixed on the one board (not shown) on the side opposite to the one side on which the slots 112 is formed.

Further, the connector 100 according to the present invention includes a male connector unit 120 that is provided with a pair of protrusions 122 inserted correspondingly into the slots 112 on the top portion of the one side of a holder 121, as shown in FIG. 4A and a fixed protrusion 123 adapted to be fixed on the other board (not shown) on the side opposite to the one side on which the protrusions 122 are formed, in the same manner as the female connector unit 110.

The female connector unit 110 is further provided with a plurality of female terminals 114 that are inserted into the slots 112. As a result, the pair of slots 112 are divided into electrodes ‘+’ and ‘−’ such that the plurality of female terminals 114 are divided into the electrodes ‘+’ and ‘−’ and inserted correspondingly into the slots 112 having the electrodes ‘+’ and ‘−’.

The male connector unit 120 is further provided with a plurality of male terminals 124 that are inserted into the protrusions 122. In the same manner as the female connector unit 110, thus, the pair of protrusions 122 are divided into electrodes ‘+’ and ‘−’ such that the plurality of male terminals 114 are divided into the electrodes ‘+’ and ‘−’ and inserted correspondingly into the protrusions 122 having the electrodes ‘+’ and ‘−’.

Each of the plurality of female terminals 114 is of a shape of “L” and has a pair of legs 115 of a shape of “U” provided with an insertion hole 117 into which each of the plurality of male terminals 124 is inserted. Each leg 115 is provided with a locking protrusion 116 that is formed on the inner side of the end portion thereof, for coupling to each of the male terminals 124, and the insertion hole 117 formed between the pair of legs 115 has a width enough to insert the leg 125 of each of the male terminals 124 therein.

Each of the plurality of male terminals 124 is of a shape of “L” and has a leg 125 as a portion connected to each of the female terminals 114 that is inserted into each of the protrusions 122 extended from the holder 121 of the male connector unit 120. Further, the leg 125 is provided with a locking protrusion 126 that is formed on the outer side of the end portion thereof, for engagement with the locking protrusion 116 of each of the female terminals 114, and the outer width of the locking protrusion 126 of the leg 125 corresponds with the width of the insertion hole 117 of each of the female terminals 114.

The plurality of female and male terminals 114 and 124 are formed by cutting working from sheet metal, not by bending working used in the conventional practice. The above cutting working is to solve the problem suffered in the conventional bending working that the terminals may lose their elasticity. Then, the female and male terminals 114 and 124 are arranged in a symmetrical pair relation and mounted in a line on the holder 111 of the female connector unit 110 and the holder 121 of the male connector unit 120.

The outer surfaces of the legs 115 of each of the female terminals 114 are surrounded by the holder 111, and the leg 125 of each of the male terminals 124 is placed to be inserted into each of the protrusions 122 of the holder 121. This can prevent the elasticity each of the plurality of female and male terminals 114 has from being lost.

Next, the female connector unit 110 is mounted on the one board and the male connector unit 120 is mounted on the other, such that the leg 125 of each of the male terminals 124 of the male connector unit 120 is inserted into the legs 115 of each of the female terminals 114, thereby making the contact between the female and male terminals.

### INDUSTRIAL APPLICABILITY

As set forth in the foregoing, there is provided a connector according to the present invention which has the following advantage: when the connector is used for a long period of time, it can prevent the loss of elasticity caused due to the heat by resistance or the impacts by external force, thereby maintaining contact in a more stable state.

While the present invention has been described with reference to a specific embodiment, the description is illustrative of the invention and is not to be construed as limiting the invention. Various modifications may occur to those skilled in the art without departing from the true spirit and scope of the invention as defined by the appended claims.

What is claimed is:

1. A connector for connecting boards that comprises a female connector unit with a pair of substantially long slots on the one side thereof and a fixed protrusion for the one board on the side opposite to the one side on which said pair of slots are formed and a male connector unit with a pair of protrusions inserted correspondingly into said pair of slots and a fixed protrusion for the other board on the side opposite to the one side on which said protrusions are formed, said connector being characterized in that said female connector unit has said pair of slots that are divided into electrodes ‘+’ and ‘−’ on the top portion of the one side thereof and a plurality of female terminals that are of a shape of “L” to be inserted into said pair of slots in a symmetrically arranged manner, each of said plurality of female terminals having a pair of legs of a shape of “U” into which each of a plurality of male terminals is connected and each of said pair of legs provided with a first locking protrusion on the inner side of the end portion thereof, and said male connector unit has said pair of protrusions that are divided into the electrodes ‘+’ and ‘−’ on the top portion of the one side thereof and inserted into said pair of slots and said plurality of male terminals that are of a shape of “L” to be inserted into said pair of protrusions in a symmetrically arranged manner, each of said plurality of male terminals having a leg as a portion connected to each of said plurality of female terminals that is inserted and fixed into each of said pair of protrusions and said leg provided with a second locking protrusion that is engaged with said first locking protrusion of each of said plurality of female terminals, on the outer side of the end portion thereof.

2. The connector as defined in claim 1, wherein said plurality of female terminals and said plurality of male terminals, which are inserted correspondingly into said female connector unit and said male connector unit, are formed by cutting working from sheet metal.
